(19) United States
(12) Patent Application Publication
(10) Pub. No.: US 2025/0062100 A1
(43) Pub. Date: Feb. 20, 2025

(54) DUAL SCAN TYPE ION IMPLANT SYSTEM

(71) Applicant: Ninebell Co., Ltd, Seongnam-si (KR)

(72) Inventors: Moon Soo CHOI, Seongnam-si (KR); Young CHOI, Yongin-si (KR); Yong Sun SOHN, Seongnam-si (KR); Jeong Sik KIM, Seoul (KR); Sung Jin JU, Seongnam-si (KR)

(73) Assignee: Ninebell Co., Ltd, Seongnam-si (KR)

(21) Appl. No.: 18/782,902

(22) Filed: Jul. 24, 2024

(30) Foreign Application Priority Data
Aug. 14, 2023 (KR) 10-2023-0106428

(51) Int. Cl. H01J 37/317; H01J 37/16; H01J 37/18; H01J 37/302

(52) U.S. Cl. CPC H01J 37/3171; H01J 37/16; H01J 37/18; H01J 37/302

(57) ABSTRACT

Proposed is a dual scan-type ion implant system including a process chamber, first and second scan robots, and an EFEM. In the process chamber, scanning is performed with an ion beam. The first and second scan robots are placed inside the process chamber. The EFEM is provided on one side of the process chamber, and is equipped with a plurality of wafer cassettes. The first and second scan robots inside the process chamber receive wafers from the EFEM along different non-overlapping wafer scan transfer paths, respectively, and then the first and second scan robots alternately perform ion beam scanning.

### CROSS REFERENCE TO RELATED APPLICATION

The present application claims priority to Korean Patent Application No. 10-2023-0106428, filed Aug. 14, 2023, the entire contents of which is incorporated herein for all purposes by this reference.

### BACKGROUND

### Field of the Invention

The present disclosure relates to a dual scan-type ion implant system. More particularly, the present disclosure relates to a dual scan-type ion implant system solving problems of a conventional single ion scan robot that handles entry and exit transportation for wafer replacement and scanning all alone and is thus unable to perform scanning during wafer transportation, which greatly reduces wafer processing efficiency (throughput) and wastes costly ion beams during transportation.

### Description of the Related Art

In general, a semiconductor device manufacturing process is conducted by repeatedly performing an oxidation process, a photo etching process, a diffusion process, an ion injection process, and a metallization process on silicon wafers.

Among the processes, the ion injection process refers to injecting charged impurities into a wafer at predetermined energy, in a desired quantity, and to a desired depth. In general semiconductor processing, the ion injection process refers to injecting dopant ions into the surface of a silicon wafer.

An ion implanter used in the ion injection process roughly includes four main parts.

These main parts may be divided into: an ion source region in which an ion beam is extracted; a terminal region including a mass analyzer for classifying the extracted ion beam into desired masses, and a beam line, which is a passage through which the ion beam passes; and an end-station region in which a wafer is transferred and the ion beam is finally injected. The end-station region includes a processor chamber in which a wafer is scanned and an ion beam is injected into the wafer in a high vacuum state.

The above-described ion implanter is also commonly referred to as a single scan-type ion implant system because one ion scan robot is provided inside a processor chamber and the one ion scan robot handles, alone, the entire process of performing entry into the processor chamber, scanning (ion injection), and exit of wafers sequentially one by one.

An example of such a single scan-type ion implant system is described in Korean Patent No. 10-1311885 (hereinafter, referred to as “the document of the related art”).

Referring to FIG. 1 of the document of the related art, wafers (W) are entered one by one from a wafer cassette 71 into a vacuum processing chamber 20 through an entry-only loadlock chamber 40A and an opening and closing door 41A installed on one side of the ion implant system, and the wafers (W) subjected to ion scanning are exited to a wafer cassette 72 through an exit-only loadlock chamber 40B and an opening and closing door 41B.

However, a conventional single scan-type ion implant system disclosed in the document of the related art has a serious problem that only one ion scan robot (called a “single ion scan robot”) is provided inside the vacuum processing chamber. This means that the single ion scan robot needs to handle entry and exit transportation for wafer replacement and scanning all alone and is thus unable to perform scanning during wafer transportation, which greatly reduces wafer processing efficiency (throughput) and wastes costly ion beams during transportation.

The foregoing is intended merely to aid in the understanding of the background of the present disclosure, and is not intended to mean that the present disclosure falls within the purview of the related art that is already known to those skilled in the art.

### SUMMARY

The present disclosure is directed to providing a dual scan-type ion implant system solving problems of a conventional single ion scan robot that handles entry and exit transportation for wafer replacement and scanning all alone and is thus unable to perform scanning during wafer transportation, which greatly reduces wafer processing efficiency (throughput) and wastes costly ion beams during transportation.

According to an embodiment of the present disclosure, there is provided a dual scan-type ion implant system including: a process chamber in which scanning is performed with an ion beam; first and second scan robots placed inside the process chamber; and an EFEM provided on one side of the process chamber, and equipped with a plurality of wafer cassettes, wherein the first and second scan robots inside the process chamber receive wafers from the EFEM along different non-overlapping wafer scan transfer paths, respectively, and then the first and second scan robots alternately perform ion beam scanning.

In addition, according to an embodiment, the dual scan-type ion implant system may further include: a first loadlock chamber assembly connected to a first end of the EFEM; a first vacuum transfer module (VTM) provided between the first loadlock chamber assembly and the process chamber; a second loadlock chamber assembly connected to a second end of the EFEM; and a second vacuum transfer module (VTM) provided between the second loadlock chamber assembly and the process chamber.

In addition, according to an embodiment, a first wafer scan transfer path among the wafer scan transfer paths may be configured for going and returning from one of the plurality of wafer cassettes, to the EFEM, to the first loadlock chamber assembly, to the first vacuum transfer module (VTM), to the process chamber, to the first scan robot, and a second wafer scan transfer path among the wafer scan transfer paths may be configured for going and returning from one of the plurality of wafer cassettes, to the EFEM, to the second loadlock chamber assembly, to the second vacuum transfer module (VTM), to the process chamber, to the second scan robot.

In addition, according to an embodiment, an ion beam irradiation region between the first and second scan robots inside the process chamber may be irradiated with the ion beam, and the first and second scan robots placed on opposite sides of the ion beam irradiation region may alternately expose the wafers to the ion beam irradiation region and perform scanning continuously.

In addition, according to an embodiment, one side of each of the first and second vacuum transfer modules (VTMs) may be provided with an aligner for aligning a notch direction of the wafer.

In addition, according to an embodiment, each of the first loadlock chamber assembly and the second loadlock chamber assembly may be divided into an upper chamber and a lower chamber for carrying the wafer into or out of the first or second vacuum transfer module (VTM).

In addition, according to an embodiment, each of the first and second vacuum transfer modules (VTMs) may maintain a high vacuum state corresponding to the process chamber, and may be internally provided with a vacuum robot for transferring the wafer between the first or second loadlock chamber assembly, an aligner, and the process chamber.

In addition, according to an embodiment, each of the first and second scan robots may include: an L1 axis vertically coupled to a first side of a first link, and configured to rotate the first link as a first drive part operates; an L2 axis vertically coupled to a second side of the first link and a first side of a second link laid thereon, and configured to rotate the second link as a second drive part operates, the second link having the same length as the first link and being laid on top of the first link; an R axis vertically coupled to a second side of the second link and a center of a support frame for supporting a scan head, and configured to rotate the support frame as a third drive part operates, the support frame being laid on top of the second side of the second link; a Y axis horizontally coupled to the support frame to support opposite sides of the scan head, and configured to rotate the scan head as a fourth drive part operates; and an S axis configured to adjust a twist angle or an orientation angle of the wafer by rotating a wafer chuck on which the wafer is placed as a fifth drive part operates, wherein the first drive part and the second drive part operate in synchronization, and the first link rotates left and right around the L1 axis and the second link rotates left and right around the L2 axis to move the scan head horizontally left and right.

The present disclosure as described above provides two wafer entry and exit paths connected to the process chamber and the two ion scan robots inside the process chamber, thereby solving the problems of the conventional single ion scan robot that handles entry and exit transportation for wafer replacement and scanning all alone, which reduces wafer processing efficiency (throughput) and wastes costly ion beams during wafer transportation.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of a conventional single scan-type ion implant system;

FIG. 2 is a plan view of a dual scan-type ion implant system according to an embodiment of the present disclosure;

FIG. 3 is an enlarged plan view of the process chamber of FIG. 2;

FIG. 4 is an enlarged perspective view of the aligner of FIG. 2;

FIG. 5 is an enlarged perspective view of the first and second loadlock chamber assemblies of FIG. 2;

FIG. 6A is an enlarged perspective view of the first and second vacuum transfer modules (VTMs) of FIG. 2, FIG. 6B is an enlarged plan view thereof, and FIG. 6C is an enlarged exploded perspective view of a vacuum robot;

FIG. 7 is a conceptual diagram illustrating a wafer beam scan method of first and second scan robots according to an embodiment of the present disclosure;

FIG. 8 is a schematic diagram illustrating the configuration of first and second scan robots according to an embodiment of the present disclosure;

FIGS. 9A and 9B are motion diagrams illustrating an operation in which left and right scanning is performed as respective drive parts for an L1 axis, an L2 axis, and an R axis of first and second scan robots operate in synchronization according to an embodiment of the present disclosure;

FIGS. 10A and 10B are motion diagrams illustrating a 45° angle tilt scanning operation of first and second scan robots according to an embodiment of the present disclosure;

FIGS. 11A and 11B are motion diagrams illustrating the operation of a scan head of first and second scan robots by driving an Y axis (tilt axis) according to an embodiment of the present disclosure;

FIGS. 12A and 12B are motion diagrams illustrating adjustment of a twist angle or orientation angle of a wafer by driving an S axis of a scan head of first and second scan robots according to an embodiment of the present disclosure;

FIG. 13 is a diagram illustrating doping uniformity during high-angle tilt ion injection into a wafer by the first and second scan robots according to an embodiment of the present disclosure; and

FIG. 14A is a diagram illustrating a state in which a first scan robot replaces a wafer at a wafer replacement position and then waits for scanning operation while a second scan robot performs scanning in the case of horizontal scanning, and FIG. 14B is a diagram illustrating the same state in the case of 45 degree angle scanning according to an embodiment of the present disclosure.

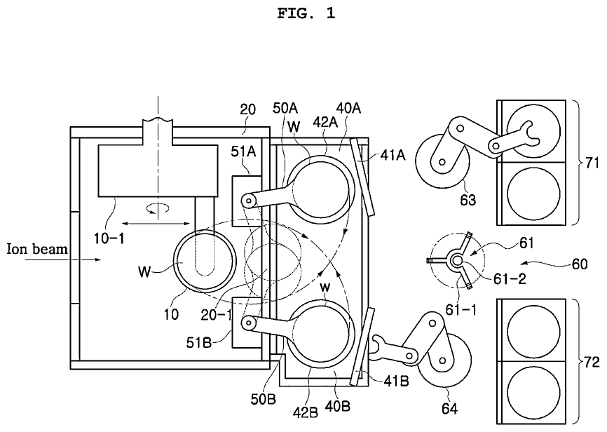

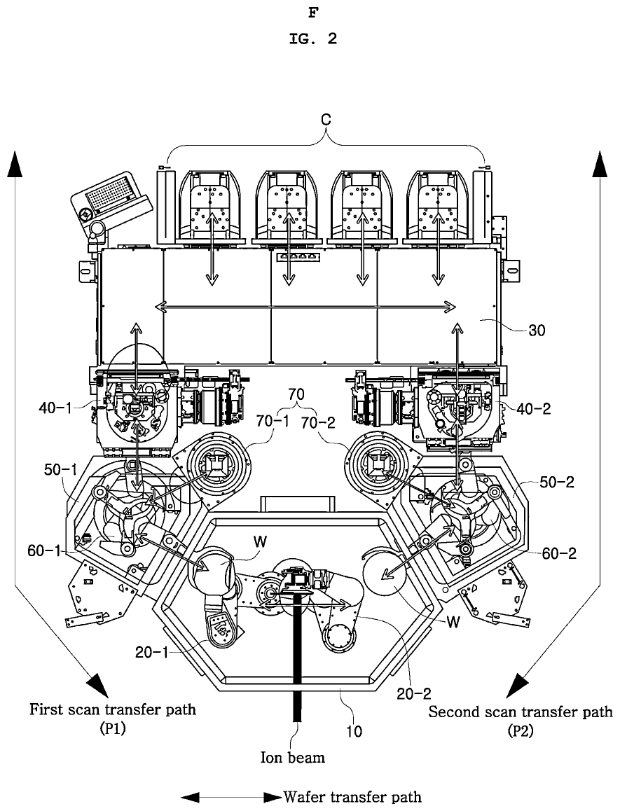

### DETAILED DESCRIPTION

The terms used in the present application are merely used to describe particular embodiments, and are not intended to limit the present disclosure. An expression used in the singular encompasses the expression of the plural, unless it has a clearly different In the present specification, it is to be meaning in the context. understood that terms such as “including”, “having”, “providing”, etc. are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Unless otherwise defined in the specification, all terms including technical and scientific terms used herein have the same meaning as commonly understood by one of ordinary skill in the art to which the present disclosure belongs.

It will be further understood that terms used herein should be interpreted as having a meaning that is consistent with their meaning in the context of this specification and the relevant art and will not be interpreted in an idealized or overly formal sense unless expressly so defined herein.

Hereinafter, with reference to the accompanying drawings, the configuration and operational relationships of a dual scan-type ion implant system according to an embodiment of the present disclosure will be described in detail as follows.

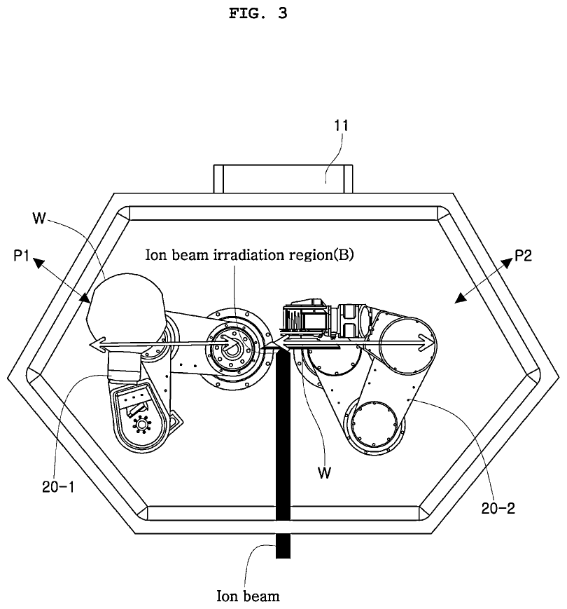

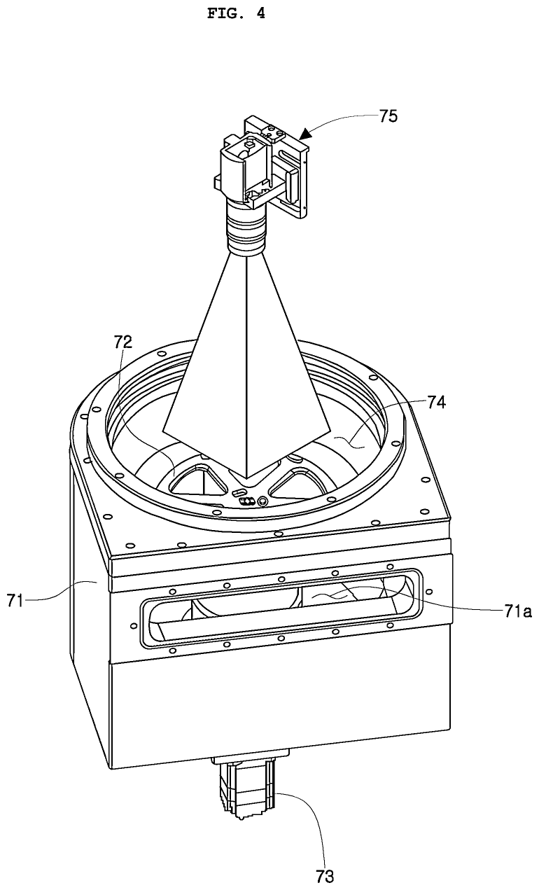

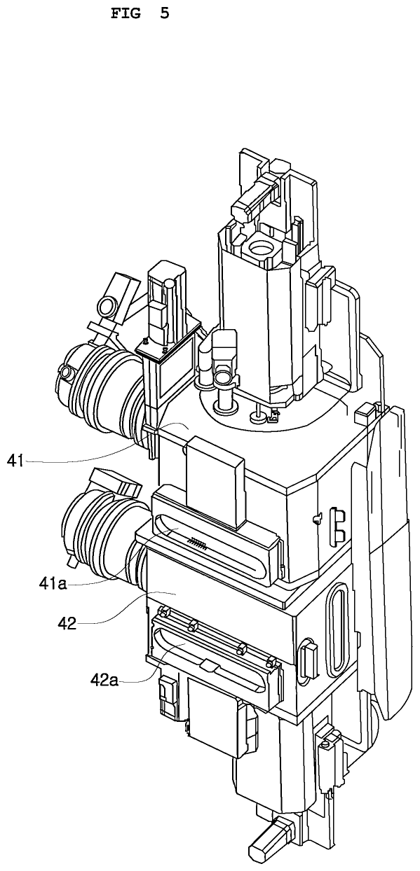

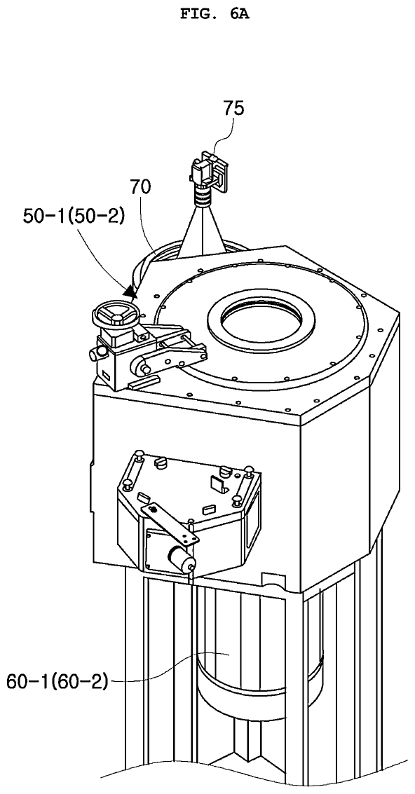

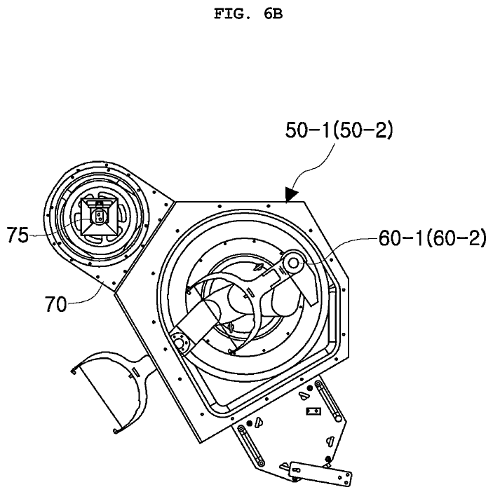

FIG. 2 is a plan view of a dual scan-type ion implant system according to an embodiment of the present disclosure. FIG. 3 is an enlarged plan view of the process chamber of FIG. 2. FIG. 4 is an enlarged perspective view of the aligner of FIG. 2. FIG. 5 is an enlarged perspective view of the first and second loadlock chamber assemblies of FIG. 2. FIG. 6A is an enlarged perspective view of the first and second vacuum transfer modules (VTMs) of FIG. 2, FIG. 6B is an enlarged plan view thereof, and FIG. 6C is an enlarged exploded perspective view of a vacuum robot.

The configuration according to an embodiment of the present disclosure will be described with reference to FIGS. 2 to 6C. The present disclosure roughly includes a process chamber 10, first and second scan robots 20-1 and 20-2, an EFEM 30, first and second loadlock chamber assemblies 40-1 and 40-2, and first and second vacuum transfer modules (VTMs) 50-1 and 50-2.

First, the process chamber 10 is the processing space where scanning (ion injection) of a wafer (W) is performed with an ion beam. Herein, the process chamber 10 is maintained at high vacuum for a clean, particle-free ion injection environment.

According to an embodiment, as shown in FIGS. 2 and 3, on one side of the process chamber 10, an ion beam is incident into the process chamber 10 and meets the wafer (W) at a point B (ion beam irradiation region) inside the process chamber 10 and scanning is performed. In the meantime, an ion beam dump 11 is provided on the side opposite to the side of the process chamber 10 at which the ion beam is incident. For example, the middle of the process chamber 10 may be irradiated with an ion beam, and the ion beam may be in the form of a ribbon beam, or a spot beam for line scanning in one direction of the electric and magnetic field. In addition, the first and second scan robots 20-1 and 20-2 respectively placed on opposite sides of the ion beam irradiation region alternately expose wafers (Ws) to the ion beam irradiation region and perform scanning continuously.

In addition, the first and second scan robots 20-1 and 20-2 are placed inside the process chamber 10. Under high vacuum, the first and second scan robots 20-1 and 20-2 carry the wafers (Ws) into or out of the process chamber 10, or perform scanning to expose the carried-in wafers (Ws) to ion beams.

Herein, unlike a conventional single scan robot, regarding the first and second scan robots 20-1 and 20-2 in the present disclosure, while one of the first and second scan robots 20-1 and 20-2 transfers the wafer (W) to carry the same into or out of the process chamber 10, the other may perform scanning. In addition, when scanning is completed, the robot that has completed transfer takes over and performs scanning continuously. Accordingly, the waste of costly ion beams is prevented.

In addition, the EFEM (equipment front end module) 30 is, typically in semiconductor lines, a standard interface module of process equipment that feeds a wafer (W) in a wafer cassette (C) or a wafer FOUP (front opening unified pod) to the process chamber 10. According to an embodiment of the present disclosure, with multiple load ports, on which a plurality of wafer cassettes (C) or wafer FOUPs placed, equipped on one side of the EFEM 30, the EFEM 30 is placed on one side of the process chamber 10.

In addition, the first loadlock chamber assembly 40-1 is connected to a first end of the EFEM 30. The first loadlock chamber assembly 40-1 is an intermediate module for inputting the wafer (W) transferred from the EFEM 30 at atmospheric pressure into the process chamber 10.

In addition, the first vacuum transfer module (VTM) is provided between the first loadlock chamber assembly 40-1 and the process chamber 10. The first vacuum transfer module (VTM) is an intermediate module in which the wafer (W) waits before being input into the process chamber 10, and maintains a high vacuum corresponding to the process chamber 10.

Hereby, a first wafer scan transfer path (Pl, see the arrows in FIG. 2) is formed for going and returning from one of the plurality of wafer cassettes (C), to the EFEM 30, to the first loadlock chamber assembly 40-1, to the first vacuum transfer module 50-1, to the process chamber 10, to the first scan robot 20-1.

In the meantime, the second loadlock chamber assembly 40-2 is connected to a second end of the EFEM 30.

In addition, the second vacuum transfer module 50-2 is provided between the second loadlock chamber assembly 40-2 and the process chamber 10.

Hereby, similarly to the first wafer scan transfer path (Pl), a second wafer scan transfer path (P2, see the arrows in FIG. 2) is formed for going and returning from one of the plurality of wafer cassettes (C), to the EFEM 30, to the second loadlock chamber assembly 40-2, to the second vacuum transfer module 50-2, to the process chamber 10, to the second scan robot 20-2.

Accordingly, in the middle of the process chamber 10, an ion beam irradiation region (S, see FIG. 3) in which a wafer (W) is irradiated with an ion beam incident into the process chamber 10 is formed. The first and second scan robots 20-1 and 20-2 placed on opposite sides of the ion beam irradiation region(S) alternately expose wafers (Ws) loaded on the first and second scan robots 20-1 and 20-2 to the ion beam irradiation region to perform scanning continuously.

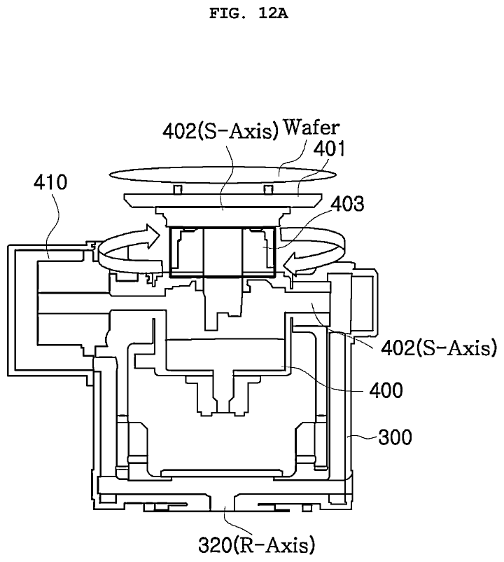

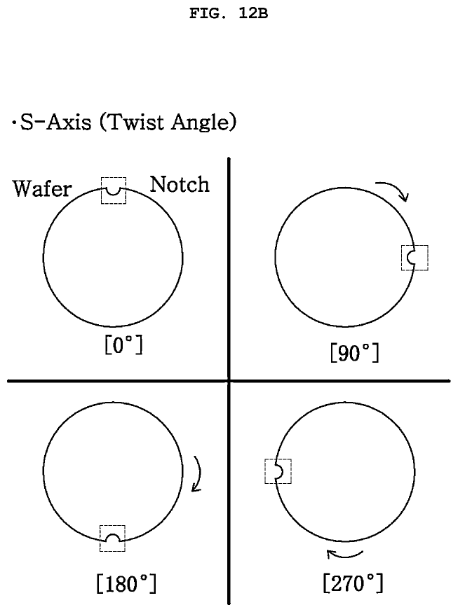

Referring to FIG. 2, according to an embodiment, one side of each of the first and second vacuum transfer modules 50-1 and 50-2 is provided with an aligner 70 for aligning a notch (see FIG. 12B) direction of a wafer (W).

More specifically, referring to FIG. 4, the aligner 70 includes: a vacuum chamber 71 provided with a wafer entry and exit slot 71a communicating with the first or second vacuum transfer module 50-1 or 50-2; a wafer chuck 72 provided in the vacuum chamber 71 and enabling the wafer (W) input through the wafer entry and exit slot 71a to sit on the wafer chuck 72; a servo motor 73 provided below the wafer chuck 72 and configured to rotate the wafer (W) loaded on the wafer chuck 72 by a predetermined angle in one direction or a reverse direction; and a vision unit 75 provided above the vacuum chamber 71 and configured to image the notch (see FIG. 12B) of the wafer (W) loaded on the wafer chuck 72, through a see-through window 74 on the top surface of the vacuum chamber 71.

Herein, according to another embodiment, the configuration of the aligner 70 is not limited to the vision unit 75 for imaging. According to another embodiment, replacing the vision unit 75, a sensor (not shown) may be used to recognize the contour and notch of the wafer (W).

In addition, referring to FIG. 5, according to an embodiment, each of the first loadlock chamber assembly 40-1 and the second loadlock chamber assembly 40-2 is divided into an upper chamber 41 and a lower chamber 42 that carry a wafer (W) into or out of the first or second vacuum transfer module 50-1 or 50-2.

For example, the upper chamber 41 is provided with a wafer entry slot 41a for carrying the wafer (W) into the first vacuum transfer module 50-1. Through the wafer entry slot 41a, the wafer (W) is forwarded to a first vacuum robot 60-1 inside the first vacuum transfer module 50-1.

Similarly, the lower chamber 42 is provided with a wafer exit slot 42a for carrying the wafer (W) out of the first vacuum transfer module 50-1. After the wafer exit slot 42a is opened, the wafer (W) to which ion injection (scanning) has been completed is forwarded from the first vacuum robot 60-1 inside the first vacuum transfer module 50-1.

In the above, the vertical division of each of the first loadlock chamber assembly 40-1 and the second loadlock chamber assembly 40-2 into the upper chamber 41 and the lower chamber 42 is arranged for space efficiency on a wafer transfer path. However, the present disclosure is not limited thereto, and the same function may be accomplished even with horizontal division arrangement.

In addition, referring to FIGS. 6A to 6C, according to an embodiment, each of the first and second vacuum transfer modules 50-1 and 50-2 maintains a high vacuum state corresponding to the process chamber 10. The first and second vacuum transfer modules 50-1 and 50-2 are internally provided with the first and second vacuum robots 60-1 and 60-2, respectively. The first or second vacuum robot 60-1 or 60-2 is for entry or exit transfer of a wafer (W) between the first or second loadlock chamber assembly 40-1 or 40-2, the aligner 70, and the process chamber 10.

Herein, according to another embodiment, it is noted that various modifications, such as the aligner 70 is installed adjacent to the EFEM 30, are possible.

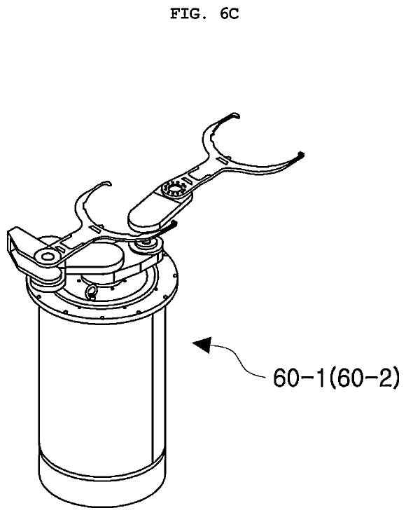

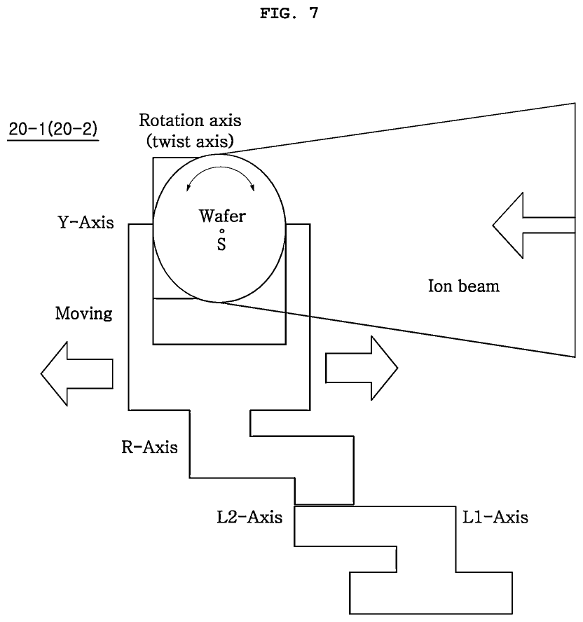

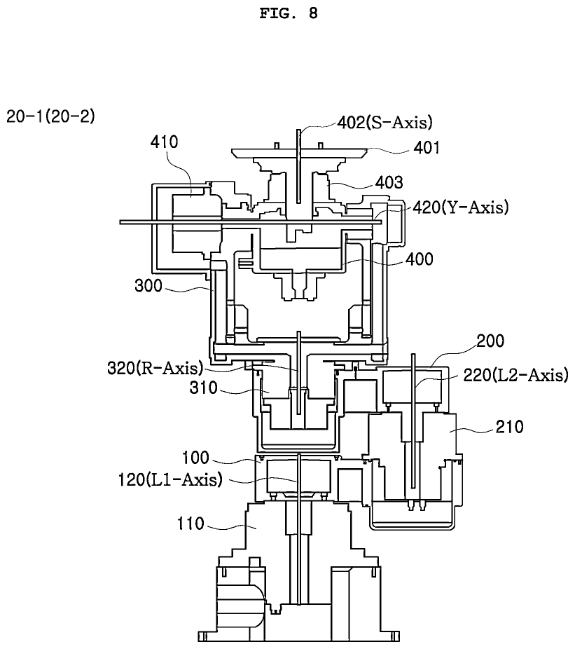

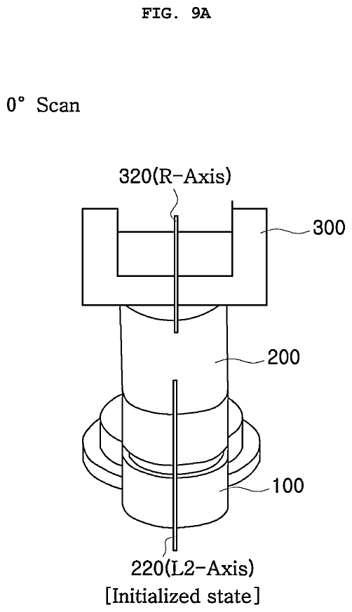

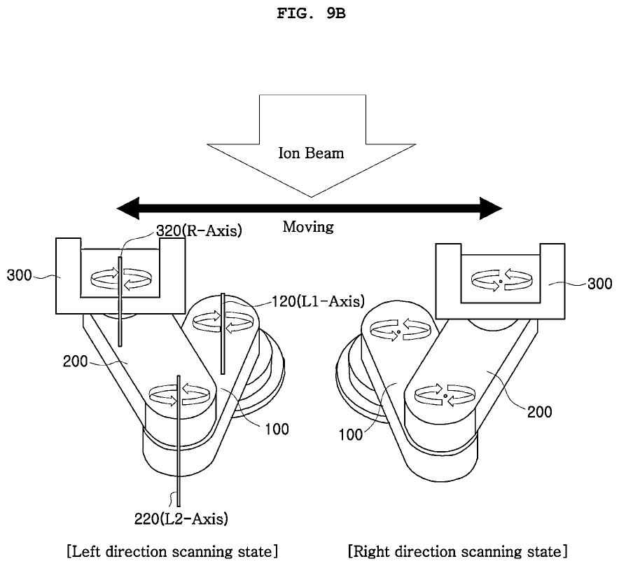

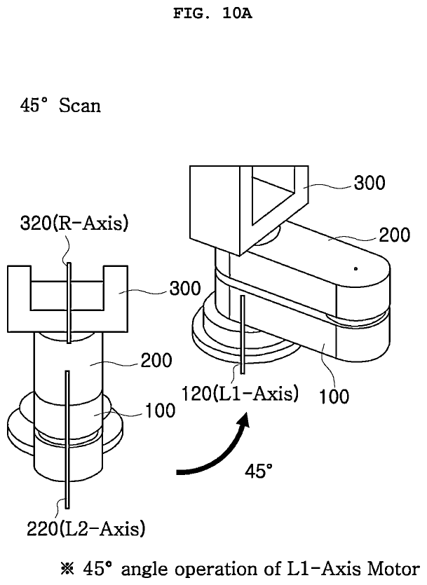

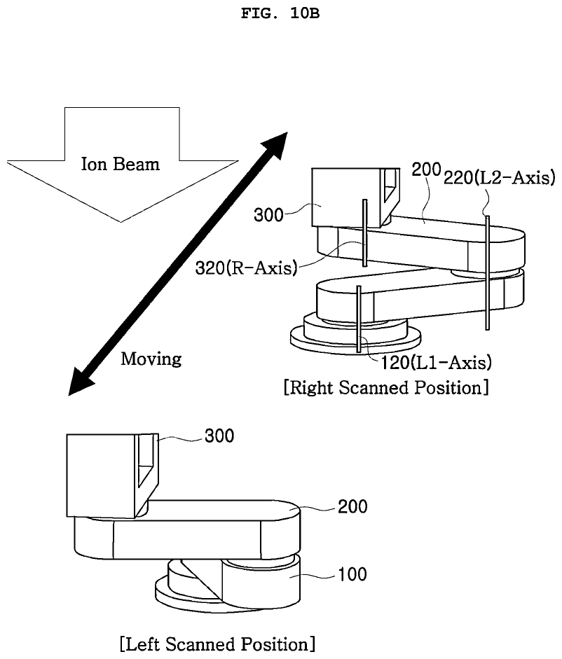

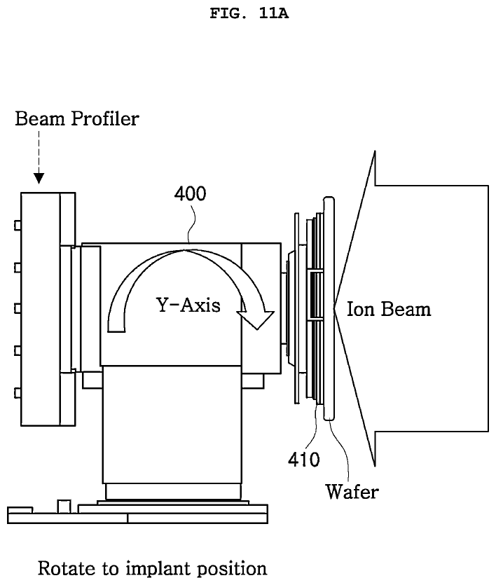

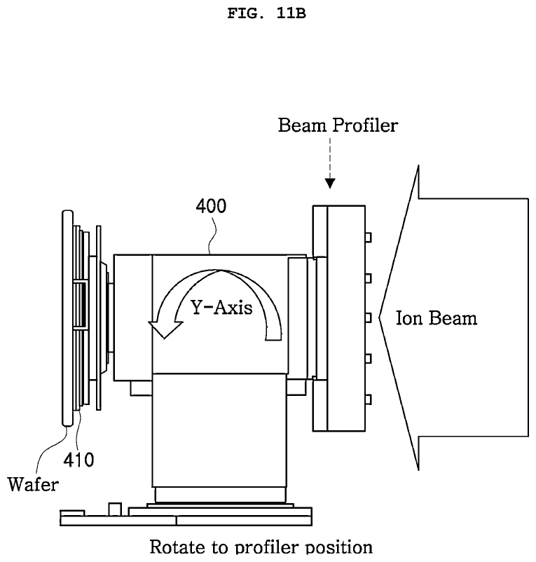

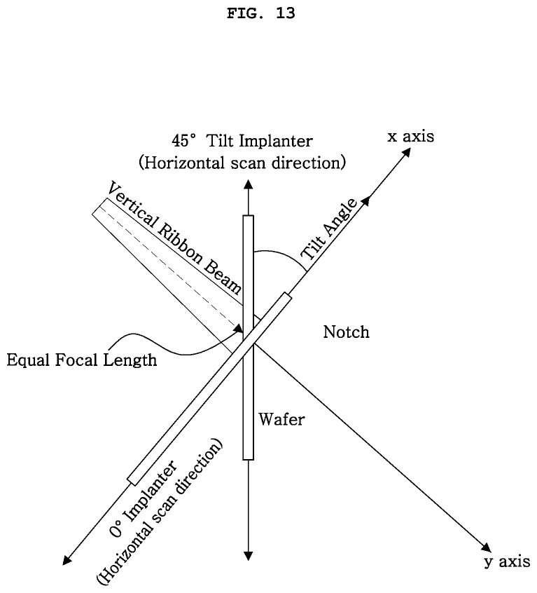

FIG. 7 is a conceptual diagram illustrating a wafer beam scan method of first and second scan robots according to an embodiment of the present disclosure. FIG. 8 is a schematic diagram illustrating the configuration of first and second scan robots according to an embodiment of the present disclosure. FIGS. 9A and 9B are motion diagrams illustrating an operation in which left and right scanning is performed as respective drive parts for an L1 axis, an L2 axis, and an R axis of first and second scan robots operate in synchronization according to an embodiment of the present disclosure. FIGS. 10A and 10B are motion diagrams illustrating a 45° angle tilt scanning operation of first and second scan robots according to an embodiment of the present disclosure. FIGS. 11A and 11B are motion diagrams illustrating the operation of a scan head of first and second scan robots by driving an Y axis (tilt axis) according to an embodiment of the present disclosure. FIGS. 12A and 12B are motion diagrams illustrating adjustment of a twist angle or orientation angle of a wafer by driving an S axis of a scan head of first and second scan robots according to an embodiment of the present disclosure. FIG. 13 is a diagram illustrating doping uniformity during high-angle tilt ion injection on a wafer by the first and second scan robots according to an embodiment of the present disclosure.

Hereinafter, with reference to FIGS. 7 to 13, the configuration and operational relationship of the first and second scan robots according to the present disclosure will be described in more detail as follows.

As shown in FIGS. 7 and 8, according to an embodiment of the present disclosure, the first and second scan robots for ion injection into a semiconductor wafer perform left and right mechanical scanning in all directions in a horizontal plane through movement of five drive shafts including an L1 axis, an L2 axis, an R axis, a Y axis (tilt axis), and an S axis with respect to a vertical scan ion beam.

First, as shown in FIG. 8, a first drive part 110 is provided under a first side of a first link 100, and the L1 axis 120, which is the drive shaft of the first drive part 110, is vertically coupled to the first side of the first link 100. The L1 axis 120 is a reference axis of the first and second scan robots 20-1 and 20-2, and rotates the first link 100 left and right as the first drive part 110 operates.

In addition, a second link 200 is laid on top of the first link 100.

A second drive part 210 is provided in a second side of the first link 100, and the L2 axis 220, which is the drive shaft of the second drive part, protrudes upward and is vertically coupled to a first side of the second link 200. The L2 axis 220 rotates the second link 200 left and right as the second drive part 210 operates.

In addition, a support frame 300 supporting a scan head 400 is laid on top of a second side of the second link 200.

A third drive part 310 is provided in the second side of the second link 200, and the R axis 320, which is the drive shaft of the third drive part 310, protrudes upward and is vertically coupled to the center of the support frame 300. The R axis 320 rotates the support frame 300 left and right as the third drive part 310 operates.

Herein, the first drive part 110, the second drive part 210, and the third drive part 310 operate in synchronization.

FIGS. 9A and 9B show 0° angle scanning. From the initial state shown in FIG. 9A, when the first drive part 110 operates, the first link 100 rotates around the L1 axis 120 as shown in FIG. 9B. When the second drive part 210, which is synchronized with the first drive part, operates, the second link 200, which has the same length as the first link, rotates around the L2 axis 220. Accordingly, the scan head 400 is horizontally moved to the left and right.

This will be described in more detail with reference to FIG. 9B. As the first drive part 110 operates, the first link 100 rotates left around the L1 axis 120. Simultaneously, as the second drive part 210 synchronized with the first drive part operates, the second link 200 rotates left around the L2 axis 220. Next, as the first drive part 110 operates, the first link 100 rotates right around the L1 axis 120. Simultaneously, as the second drive part 210 synchronized with the first drive part operates, the second link 200 rotates right around the L2 axis 220. Accordingly, the scan head 400 is moved horizontally to the left and right. Simultaneously, as the third drive part 310, which is synchronized with the first drive part 110, operates, the scan head 400 rotates left and right around the R axis 320. Herein, the R axis 320 makes adjustment so that an incident angle of an ion beam is constant in the left and right scanning process.

That is, the scan head 400 implements scalar motion capable of scanning in any specified horizontal direction through simultaneous rotation of the L1 axis 120, the L2 axis 220, and the R axis 320.

In addition, FIGS. 10A and 10B show 45° angle tilt scanning. From the initial state of a 0° angle as shown in FIG. 10A, the L1 axis 120, which is the reference, is rotated by a 45° angle. Herein, when the first drive part 110 operates to rotate the L1 axis 120 by a 45° angle, the first link 100, the second link 200, and the scan head 400 rotate by a 45° angle. In addition, with the scan head 400 tilted by a 45° angle, the scan head 400 is moved horizontally to the left and right as shown in FIG. 10B. Herein, the left and right horizontal movement of the scan head 400 is the same as described above with reference to FIG. 9B.

That is, the scan head 400 implements scalar motion capable of scanning in any horizontal specified direction while tilted by a 45° angle.

In the meantime, the scan head 400 supported by the support frame 300 is coupled to a Y axis 420 (tilt axis) horizontally coupled to the support frame.

As shown in FIG. 8, a fourth drive part 410 is provided on one side of the support frame 300, and the Y axis 420, which is the drive shaft of the fourth drive part 410, is horizontally coupled to the support frame 300 to support the opposite sides of the scan head 400, and rotates the scan head 400 as the fourth drive part 410 operates.

As shown in FIGS. 11A and 11B, the Y axis 420, which rotates as the fourth drive part 410 operates, rotates the scan head 400 to a wafer loading or unloading position, or rotates a wafer on the wafer chuck of the scan head to an ion injection position or a beam profiling position.

As shown in FIG. 12A, the scan head 400 includes: a wafer chuck 401 for holding a wafer; an S axis 402 for rotating the wafer chuck 401; and a fifth drive part 403 for driving the S axis 402.

In addition, as shown in FIG. 12B, the S axis 402 is perpendicular to the Y axis 420, and rotates the wafer chuck 401 on which a wafer is placed as the fifth drive part 403 operates, so as to adjust a twist angle or an orientation angle of the wafer.

Herein, there are two reasons for adjusting a tilt angle and a twist angle during ion injection. First, to avoid a beam channeling phenomenon occurring in a semiconductor crystal direction, a beam incident angle needs to be adjusted in a crystal direction in which channeling is difficult. Second, recently, a semiconductor having a 3D structure requires ion injection at various angles.

According to the present disclosure, scalar motion capable of scanning in any specified horizontal direction is implemented through the motion of the L1 axis 120 and the L2 axis 220. In a left and right scanning process, an incident angle of an ion beam is adjusted through the motion of the R axis 320 so as to be constant. A twist angle or an orientation angle of a wafer is adjusted through the motion of the S axis 402.

FIG. 13 is a diagram illustrating doping uniformity during high-angle tilt ion injection into a wafer by the first and second scan robots according to an embodiment of the present disclosure.

As shown in FIG. 13, during 0° angle tilt ion injection (0° angle tilt implantation), the first and second scan robots 20-1 and 20-2 perform wafer scanning at uniform ion beam density with an ion beam equidistant from all positions on a wafer.

In addition, even for high-angle tilt, left-right wafer scanning is performed with respect to a vertical ribbon beam or a vertical scan beam, so there is no beam path difference at any point on a wafer, regardless of a tilt angle. Accordingly, beam uniformity is maintained constant during wafer scanning and ions are uniformly injected at all positions on a wafer.

As described above, the present disclosure can scan a wafer in any specificed horizontal direction so that an ion beam is uniformly injected into the wafer. In addition, even for low-energy ion injection at a high tilt angle, an ion beam equidistant from everywhere on a wafer is emitted, thus significantly improving the doping uniformity on the wafer.

In addition, the present disclosure can solve the doping uniformity problem caused by the difference in distance of an ion beam path for each wafer position in an existing scan direction and by the resulting change in ion beam size. Furthermore, the present disclosure meets doping uniformity requirements of next generation semiconductors.

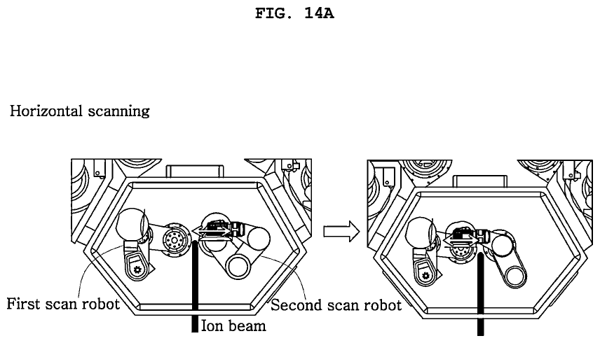

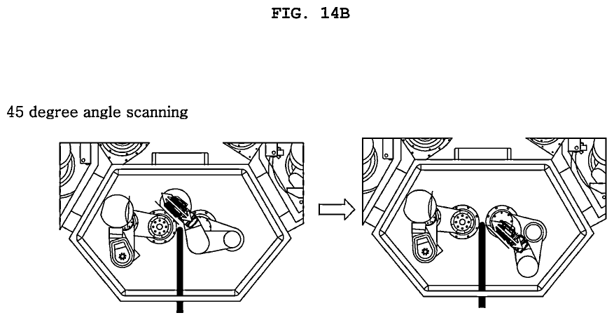

FIG. 14A is a diagram illustrating a state in which a first scan robot replaces a wafer at a wafer replacement position and then waits for scanning operation while a second scan robot performs scanning in the case of horizontal scanning, and FIG. 14B is a diagram illustrating the same state in the case of 45 degree angle scanning according to an embodiment of the present disclosure.

As described above, while any one of the first and second scan robots of the present disclosure performs scanning operation, the other waits for scan operation while replacing a wafer. Accordingly, first and second scan robots alternately perform scan operations without interruption.

The present disclosure is not limited to the above-described embodiments, and the same effect can be created even if the detailed configurations or numbers, and the arrangements of devices are changed. Accordingly, those skilled in the art will appreciate that various additions, deletions, and modifications are possible within the scope of the technical idea of the present disclosure.

1. A dual scan-type ion implant system, comprising:
a process chamber in which scanning is performed with an ion beam;
first and second scan robots placed inside the process chamber; and
an EFEM provided on one side of the process chamber, and equipped with a plurality of wafer cassettes,
wherein the first and second scan robots inside the process chamber receive wafers from the EFEM along different non-overlapping wafer scan transfer paths, respectively, and then the first and second scan robots alternately perform ion beam scanning.

2. The dual scan-type ion implant system of claim 1, further comprising:
a first loadlock chamber assembly connected to a first end of the EFEM;
a first vacuum transfer module (VTM) provided between the first loadlock chamber assembly and the process chamber;
a second loadlock chamber assembly connected to a second end of the EFEM; and
a second vacuum transfer module (VTM) provided between the second loadlock chamber assembly and the process chamber.

3. The dual scan-type ion implant system of claim 2, wherein a first wafer scan transfer path among the wafer scan transfer paths is configured for going and returning from one of the plurality of wafer cassettes, to the EFEM, to the first loadlock chamber assembly, to the first vacuum transfer module (VTM), to the process chamber, to the first scan robot, and
a second wafer scan transfer path among the wafer scan transfer paths is configured for going and returning from one of the plurality of wafer cassettes, to the EFEM, to the second loadlock chamber assembly, to the second vacuum transfer module (VTM), to the process chamber, to the second scan robot.

4. The dual scan-type ion implant system of claim 1, wherein an ion beam irradiation region between the first and second scan robots inside the process chamber is irradiated with the ion beam, and the first and second scan robots placed on opposite sides of the ion beam irradiation region alternately expose the wafers to the ion beam irradiation region and perform scanning continuously.

5. The dual scan-type ion implant system of claim 2, wherein one side of each of the first and second vacuum transfer modules (VTMs) is provided with an aligner for aligning a notch direction of the wafer.

6. The dual scan-type ion implant system of claim 2, wherein each of the first loadlock chamber assembly and the second loadlock chamber assembly is divided into an upper chamber and a lower chamber for carrying the wafer into or out of the first or second vacuum transfer module (VTM).

7. The dual scan-type ion implant system of claim 2, wherein each of the first and second vacuum transfer modules (VTMs) maintains a high vacuum state corresponding to the process chamber, and is internally provided with a vacuum robot for transferring the wafer between the first or second loadlock chamber assembly, an aligner, and the process chamber.

8. The dual scan-type ion implant system of claim 1, wherein each of the first and second scan robots includes:
an L1 axis vertically coupled to a first side of a first link, and configured to rotate the first link as a first drive part operates;
an L2 axis vertically coupled to a second side of the first link and a first side of a second link laid thereon, and configured to rotate the second link as a second drive part operates, the second link having the same length as the first link and being laid on top of the first link;
an R axis vertically coupled to a second side of the second link and a center of a support frame for supporting a scan head, and configured to rotate the support frame as a third drive part operates, the support frame being laid on top of the second side of the second link;
a Y axis horizontally coupled to the support frame to support opposite sides of the scan head, and configured to rotate the scan head as a fourth drive part operates; and
an S axis configured to adjust a twist angle or an orientation angle of the wafer by rotating a wafer chuck on which the wafer is placed as a fifth drive part operates,
wherein the first drive part and the second drive part operate in synchronization, and the first link rotates left and right around the L1 axis and the second link rotates left and right around the L2 axis to move the scan head horizontally left and right.
